(19) United States
(12) Patent Application Publication
(10) Pub. No.: US 2011/0089470 A1
(43) Pub. Date: Apr. 21, 2011

(54) SEMICONDUCTOR DEVICE HAVING LAYOUT OF LOGIC CELL AND INTERFACE CELL WITH UNIFICATION OF TRANSISTOR ORIENTATION

(76) Inventor: MUTSUMI AOKI, Tokyo (JP)

(21) Appl. No.: 12/904,888

(22) Filed: Oct. 14, 2010

(30) Foreign Application Priority Data
Oct. 20, 2009 (JP) P2009-241254

(51) Int. Cl. H01L 27/118; B65G 47/22

(52) U.S. Cl. 257/203; 414/816; 257/E27.11

(57) ABSTRACT

In a semiconductor device, a plurality of interface cells is disposed on four sides of an LSI chip in connection with a logic circuit area including a plurality of logic cells. Each interface cell may include four functional blocks which are vertically or horizontally aligned without being rotated, thus forming an I/O buffer. The left I/O buffer has a vertical layout in which functional blocks are vertically aligned, whilst the upper I/O buffer has a horizontal layout in which functional blocks are horizontally aligned. This makes it possible to fix the same length direction of gates of transistors with respect to both the functional blocks of I/O buffers and the logic cells, so that engineers do not need to consider characteristic variations of transistors due to positional differences of transistors when designing the circuitry of an LSI chip.

The present application claims priority on Japanese Patent. Application No. 2009-241254, the content of which is incorporated herein by reference.

### BACKGROUND OF THE INVENTION

1. Field of the Invention

The present invention relates to semiconductor devices such as LSI devices including logic cells (or logic circuit areas serving as cores of LSI chips) and interface cells (e.g. I/O buffers and I/O macros) in which transistors are aligned in a single direction of orientation.

2. Description of the Related Art

In manufacturing of LSI devices, it is well known to engineers that characteristic variations of transistors occur due to directional differences of gates of transistors in connection with dispersions of gate exposure/rendering processes and gate shadowing effects of ion implantations as well as fluctuating precisions of photo-masks (or reticles). Recently, semiconductor devices have been developed with microprocessing technologies so that engineers cannot neglect characteristic variations of transistors due to differences of orientations of transistors.

In logic circuit areas serving as cores of LSI chips, engineers perform layout processing so as to align transistors in a single direction of orientation in standard cells, i.e. units of functional blocks. In semiconductor devices subjected to the above layout processing, transistors are basically aligned in a single direction of orientation. In interface cells (e.g. I/O buffers and I/O macros) disposed along four sides of LSI chips, transistors need to be rotated at 90 degrees or 270 degrees; this makes it difficult to unify the direction of orientation among transistors.

Since interface cells are generally disposed along four sides of LSI chips, upper/lower interface cells need to be rotated at 90/270 degrees compared to left/right interface cells. FIG. 9 shows a conventionally-known layout of I/O buffers in an LSI chip.

Specifically, FIG. 9 shows a bidirectional layout of I/O buffers 11D and 12D. Herein, the left I/O buffer 11d includes four regions 1A through 4A, each of which further includes a plurality of transistors T and gates G (i.e. gate wiring layers).

An input/output circuit for inputting/outputting signals from/to logic cell (belonging to a logic circuit area) and a level conversion circuit for converting a core voltage into an I/O voltage are disposed in the region 1A of the I/O buffer 11D. A CDM-ESD (i.e. testing using a charged device model (CDM) and an electrostatic destruction (ESD)) protective component, an output pre-buffer, and an input sense amplifier are disposed in the region A2. An output main buffer (juxtaposed to a P-channel transistor) and an ESD protective component are disposed in the region A3. An output main buffer (juxtaposed to an N-channel transistor) and an ESD protective component are disposed in the region A4.

Components of the left I/O buffer 11D are normally aligned in a Y-axis direction. When an I/O buffer is disposed along an upper/lower side of an LSI chip, it needs to be rotated at 90/270 degrees so that components thereof are aligned in an X-axis direction. Occasionally, an already-rotated I/O buffer needs to be inverted in an X-axis direction, which is known as a mirror orientation. FIG. 9 shows that the I/O buffer 11D is rotated at 90 degrees so as to form an I/O buffer 12D including the regions 1A through 4A, which are aligned in an X-axis direction.

FIG. 10 shows a conventionally-known layout of I/O buffers (or I/O macros) 21A through 24A and a logic circuit area (serving as a standard cell) 13 in an LSI chip.

As shown in FIG. 10, transistors T included in the left/right I/O buffers 21A and 22A do not agree with transistors T included in the logic circuit area 13 (serving as a core of an LSI chip) and transistors T included in the upper/lower I/O buffers 23A and 24A in terms of orientations of transistors T and gates G (i.e. gate wiring layers). Noncoincidence of orientations of transistors may cause characteristic variations; hence, engineers seek for a solution. In this connection, Patent Documents 1 to 4 disclose relevant arts with regard to chip layouts (or floor plans) in semiconductor devices.
Patent Document 1: Japanese Patent Application Publication No. 2001-51957
Patent Document 2: Japanese Patent Application Publication No. 2002-26130
Patent Document 3: Japanese Patent Application Publication No. 2008-198756
Patent Document 4: Japanese Patent Application Publication No. 2008-218751

Patent Document 1 discloses an on-chip multiprocessor illustrating a chip layout (or a floor plan) for efficiently controlling interactions between multiprocessors. Herein, common areas between multiprocessors are linear-symmetrically aligned with respect to a desired line, wherein control portions interacting with multiprocessors are aligned in regions including the desired line.

Patent Document 2 discloses a semiconductor integrated circuit constituted of I/O blocks each aligned with a single I/O pitch, wherein an optimum band pitch can be selected in response to a desired I/O number.

Patent Document 3 discloses a semiconductor device which aims to eliminate operational faults due to an IR drop (or a resistance drop of voltage) while suppressing an enlargement of a chip area without rendering unnecessary power lines.

Patent Document 4 discloses a semiconductor device in which I/O cells can be aligned in both of a vertical orientation and a horizontal orientation. That is, I/O cells having rectangular shapes are aligned such that contact positions between I/O cells and power lines are not uniformly aligned in both the long-side direction and the short-side direction of each I/O cell.

Patent Documents 1 to 4 are irrelevant to a solution to the concoincidence of transistor orientations between interface cells and logic circuit areas.

As described above, interface cells (e.g. I/O buffers or I/O macros) are normally aligned along four sides of an LSI chip so that upper/lower interface cells are rotated at 90/270 degrees compared to left/right interface cells, wherein engineers cannot neglect characteristic variations of transistors due to transistor orientations. In actuality, semiconductor vendors may not normally assure that SPICE (i.e. Simulation Program with Integrated Circuit Emphasis) parameters for use in circuit simulations have been determined in light of directional differences of gates of transistors being rotated at 90/270 degrees. This indicates a possibility that actual transistor characteristics may be deviated from SPICE parameters. For this reason, engineers need to design the layout of an LSI chip with a sufficient margin between neighboring cells or to incorporate an additional circuit for correcting dispersions of transistor characteristics.

### SUMMARY OF THE INVENTION

The present invention seeks to solve the above problem, or to improve upon the problem at least in part.

It is an object of the present invention to provide a semiconductor device in which interface cells such as I/O buffers and/or I/O macros are aligned along four sides of an LSI chip and in which interface cells agree with a logic circuit area in terms of transistor orientations regardless of aligned directions of interface cells.

A semiconductor device of the present invention includes a plurality of logic cells, and a plurality of interface cells (e.g. I/O buffers) which are disposed in connection with logic cells. Each interface cell is configured of a plurality of functional blocks each including a plurality of transistors having gates whose length direction agrees with the length direction of gates of transistors included in each logic cell.

The I/O buffer includes a first functional block which further includes an input/output circuit for inputting/outputting signals with each logic cell and a level conversion circuit for converting a core voltage into an I/O voltage, a second functional block which further includes an output pre-buffer and an input sense amplifier, a third functional block which further includes an output main buffer juxtaposed to a P-channel transistor, and a fourth functional block which further includes an output main buffer juxtaposed to an N-channel transistor.

The semiconductor device further includes a power-wiring structure having a mesh structure constituted of a first power-wiring layer and a second power-wiring layer both of which are formed above interface cells and logic cells. The first power-wiring layer conducts power wirings in a vertical direction corresponding to the length direction of gates of transistors, whilst the second power-wiring layer conducts power wirings in a horizontal direction perpendicular to the length direction of gates of transistors.

Specifically, each interface cell is configured of m×n functional blocks (where m, n are integers not less than “2”) in which m functional blocks are serially aligned together whilst n sets of m functional blocks are juxtaposed together, so that the length direction of gates of transistors included in m×n functional blocks agrees with the length direction of gates of transistors included in logic cells.

Alternatively, each interface cell serves as an I/O macro including an I/O unit and a logic unit which are connected together. The I/O unit is configured of m×n functional blocks (where m, n are integers not less than “2”) in which in functional blocks are serially aligned together whilst n sets of m functional blocks are juxtaposed together. The logic unit is configured of m′×n functional blocks (where m′ is an integer not less than “2”) in which m′ functional blocks are serially aligned together whilst n sets of m′ functional blocks are juxtaposed together. Herein, the same length direction of gates of transistors is uniformly set to logic cells, m×n functional blocks included in the I/O unit, and m′×n functional blocks included in the logic unit.

The present invention provides engineers with a vertical layout in which functional blocks are vertically aligned and a horizontal layout in which functional blocks are horizontally aligned when designing the overall circuitry of an LSI chip including interface cells and logic cells, wherein an interface cell having a vertical layout of functional blocks is disposed on the left/right side of an LSI chip whilst an interface cell having a horizontal layout of functional blocks is disposed on the upper/lower side of an LSI chip. This makes it possible for engineers to fix the same length direction of gates of transistors with respect to interface cells and logic cells without considering characteristic variations of transistors due to directional differences of transistors.

### BRIEF DESCRIPTION OF THE DRAWINGS

These and other objects, aspects, and embodiments of the present invention will be described in more detail with reference to the following drawings.

FIG. 1 shows a layout of I/O buffers in a semiconductor device according to a first embodiment of the present invention.

FIG. 2 shows a layout of a power-wiring structure including upper/lower power-wiring layers formed above I/O buffers and logic circuit areas.

FIG. 3 shows that functional blocks of each I/O buffer are replaced with other functional blocks by changing main buffers.

FIG. 4 shows a layout of an LSI chip according to the first embodiment.

FIG. 5 shows a layout of I/O buffers in a semiconductor device according to a second embodiment of the present invention.

FIG. 6 shows a layout of I/O buffers in a semiconductor device according to a third embodiment of the present invention.

FIG. 7 shows a layout of I/O buffers in a semiconductor device according to a fourth embodiment of the present invention.

FIG. 8 shows layouts for I/O macros in a semiconductor device according to a fifth embodiment of the present invention.

FIG. 9 shows a conventionally-known layout of an I/O buffer whose components are aligned in either a vertical direction or a horizontal direction.

FIG. 10 shows a conventionally-known layout of I/O buffers along four sides of an LSI chip in connection with a logic circuit area.

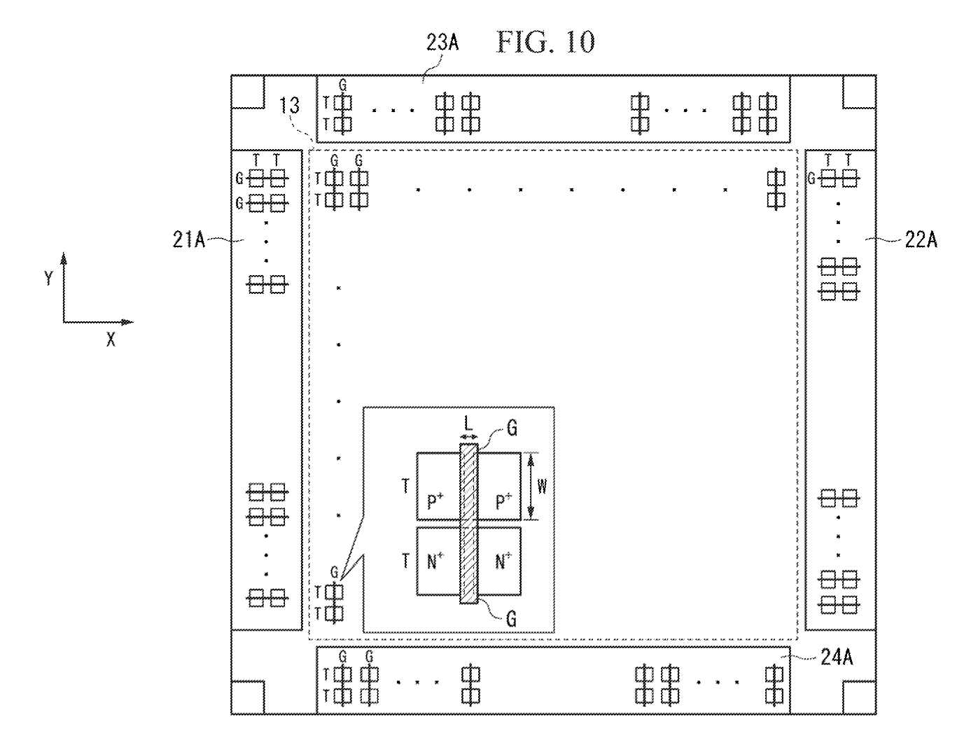

### DESCRIPTION OF THE PREFERRED EMBODIMENTS

The present invention will be described in further detail by way of examples with reference to the accompanying drawings.

The present invention presents a semiconductor device including interface cells (e.g. I/O buffers and I/O macros) and logic circuit areas, wherein length directions of gates of transistors included in interface cells agree with length directions of gates of transistors included in logic circuit areas even when each interface cell is aligned along any one of left/right sides and upper/lower sides of an LSI chip, thus eliminating characteristic variations of transistors due to differences of transistor orientations between interface cells and logic circuit areas.

### 1. First Embodiment

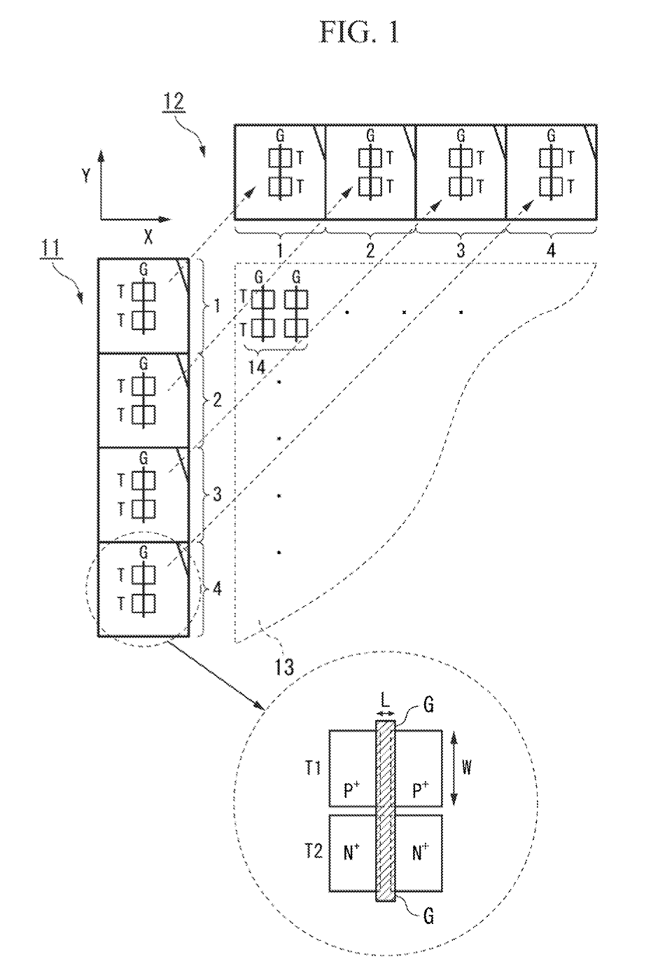

FIG. 1 shows a layout of a semiconductor device according to a first embodiment of the present invention, i.e. a layout of interface cells such as I/O buffers.

Interface cells are connected to logic cells in a logic circuit area so that interface cells input signals (output from an external device) into logic cells and output signals from logic cells to an external device (not shown). In addition, interface cells serve as interfaces inputting/outputting signals with logic cells. Each interface cell may correspond to one functional block (which is constituted of cells collectively achieving a specific function), or each interface cell may be constituted of two or more functional blocks.

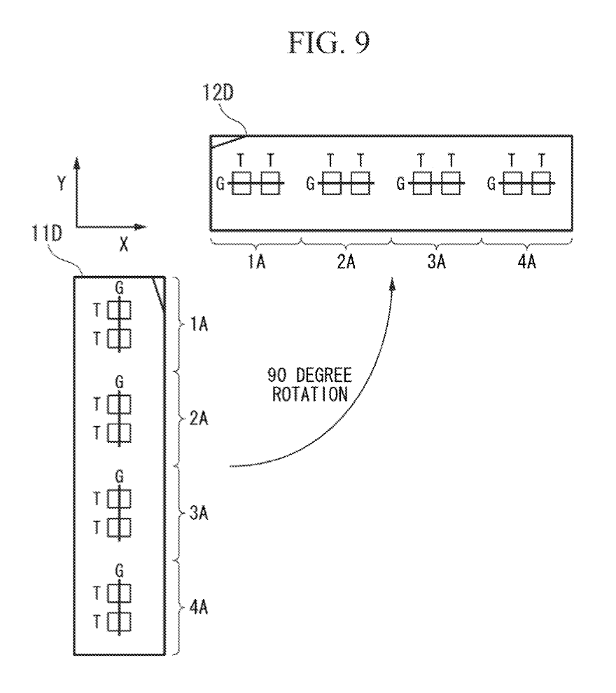

Similar to the foregoing layout of FIG. 9, FIG. 1 shows a bidirectional layout of interface cells, i.e. I/O buffers 11 and 12. The layout of FIG. 1 differs from the layout of FIG. 9 in that each interface cell is configured of a plurality of functional blocks each having a rectangular shape (i.e. a square shape). Specifically, the I/O buffers 11 and 12 are each configured of functional blocks 1, 2, 3, and 4 which are vertically/horizontally aligned together.

The functional blocks 1 to 4 are each configured of a plurality of transistors T having gates G which are illustrated using symbols showing a length direction of gates G A dotted circle in FIG. 1 is an enlarged view showing a detailed configuration consisting of two transistors coupled together. Specifically, the functional blocks 1 to 4 are each configured of a P-channel MOS transistor T1 and an N-channel MOS transistor T2, in which a gate G (or a gate wiring layer) is disposed in a vertical direction across gate regions (or channel regions) of the transistors T1 and T2.

An input/output circuit for inputting/outputting signals to/from a logic cell 14 included in the logic circuit area 13, and a level conversion circuit for converting a core voltage (applied to the logic circuit area 13) into an I/O voltage are disposed in the functional block 1 of the I/O buffer 11. A CDM-ESD protective component, an output pre-buffer, and an input pre-buffer are disposed in the functional block 2. An output main buffer (juxtaposed to the P-channel transistor T1) and an ESD protective component are disposed in the functional block 3. An output main buffer (juxtaposed to the N-channel transistor T2) and an ESD component are disposed in the functional block 4.

The I/O buffer 11 along the left side of an LSI chip has a vertical layout in which the functional blocks 1 to 4 are vertically aligned in a Y-axis direction. The I/O buffer 12 along the upper side of an LSI chip has a horizontal layout in which the functional blocks 1 to 4 are horizontally aligned in an X-axis direction. It is noted that the functional blocks 1 to 4 are not rotated at 90 degrees in the I/O buffer 12 compared to the I/O buffer 11, so that the functional blocks 1 to 4 are each realigned in parallel between the I/O buffer 11 and the I/O buffer 12. That is, the functional blocks 1 to 4, which are once vertically aligned in the I/O buffer 11 in a Y-axis direction, are directly moved along dotted arrows and horizontally realigned in the I/O buffer 12 in the X-axis direction such that the overall direction of the gate G and the transistors T are not changed at all.

The above parallel translation is able to unify the overall direction of the gate G and the transistors T among the functional blocks 1 to 4 irrespective of the left I/O buffer 11 and the upper I/O buffer 12, wherein the overall direction of the gate G and the transistor T in the I/O buffer 11/12 agrees with the overall direction of the gate G and the transistors T in the logic circuit area 13. Thus, engineers do not need to consider characteristic variations of transistors due to differences of transistor directions.

In this connection, it is necessary to independently perform wiring processes connecting between functional blocks with respect to the vertical layout (of the I/O buffer 11) and the horizontal layout (of the I/O buffer 12); hence, different wiring directions and lengths must be applied to the I/O buffers 11 and 12. Metal wiring using copper and aluminum differ from transistors in that it can neglect dispersions due to differences of wiring directions, and it can precisely form resistances and capacitances in light of wiring lengths. For this reason, engineers may easily estimate influences due to different wiring directions and lengths in advance by use of various DA tools (i.e. Design Automation Tool); hence, engineers can overcome problems due to different wiring directions and lengths. In addition, engineers may be able to invent new layouts in which the I/O buffers 11 and 12 have the same wiring length connecting between functional blocks.

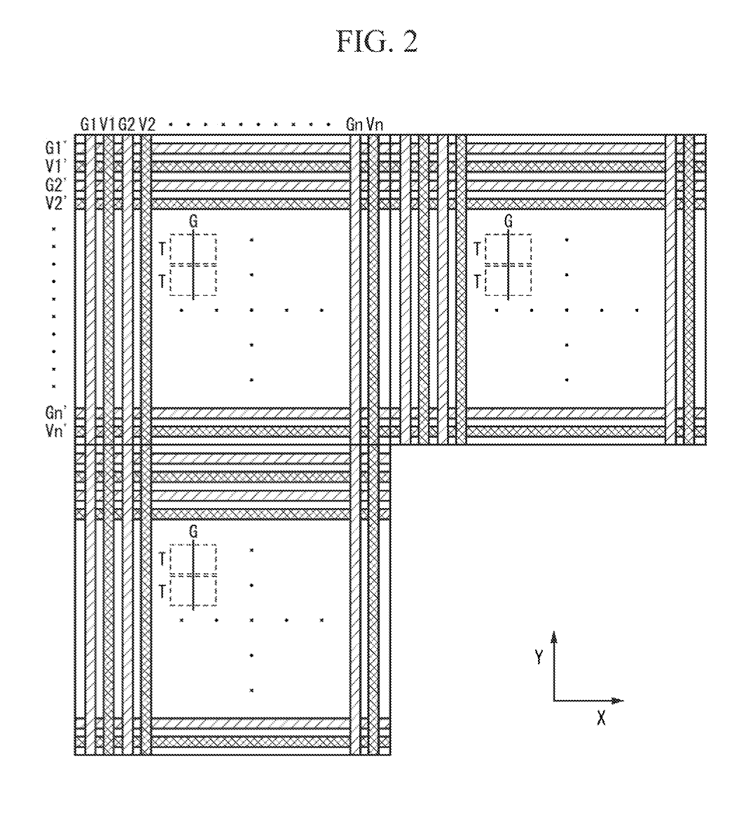

FIG. 2 shows a power-wiring structure formed above I/O buffers and logic circuit areas. The power-wiring structure adopts at least two layers (i.e. upper/lower power-wiring layers) having small resistances just above power bumps of functional blocks so that the power-wiring structure has a mesh structure in which the same layout is formed in both the vertical direction and the horizontal direction.

Specifically, the upper power-wiring layer includes ground lines G1, G2, . . . , Gn and power lines V1, V2, . . . , Vn, which are aligned in parallel in a Y-axis direction, while the lower power-wiring layer includes ground lines G1′, G2′, . . . , Gn′ and power lines V1′, V2′, . . . , Vn′, which are aligned in parallel in an X-axis direction.

The above power-wiring structure facilitates power designs with both the vertical layout and the horizontal layout because power lines (and ground lines) can be precisely connected to the functional blocks 1, 2, 3, and 4 in the I/O buffers 11 and 12, which are simply aligned to adjoin together. In this connection, each functional block can be configured as a closed circuit independently when the lower power-wiring layer (including the ground lines G1′ through Gn′ and power lines V1′ through Vn′) satisfies a restriction to an IR drop (or a power drop).

The present embodiment has another technical feature in which an I/O buffer having an arbitrary function can be easily formed by simply replacing/merging functional blocks. Referring to FIG. 9, in which an output driver has an impedance of 20Ω, it is possible to change the impedance into 40Ω by changing main buffers of the functional blocks 3 and 4, thus implementing other functional blocks 3′ and 4′. Replacement of functional blocks is not necessarily limited to the functional blocks 3 and 4.

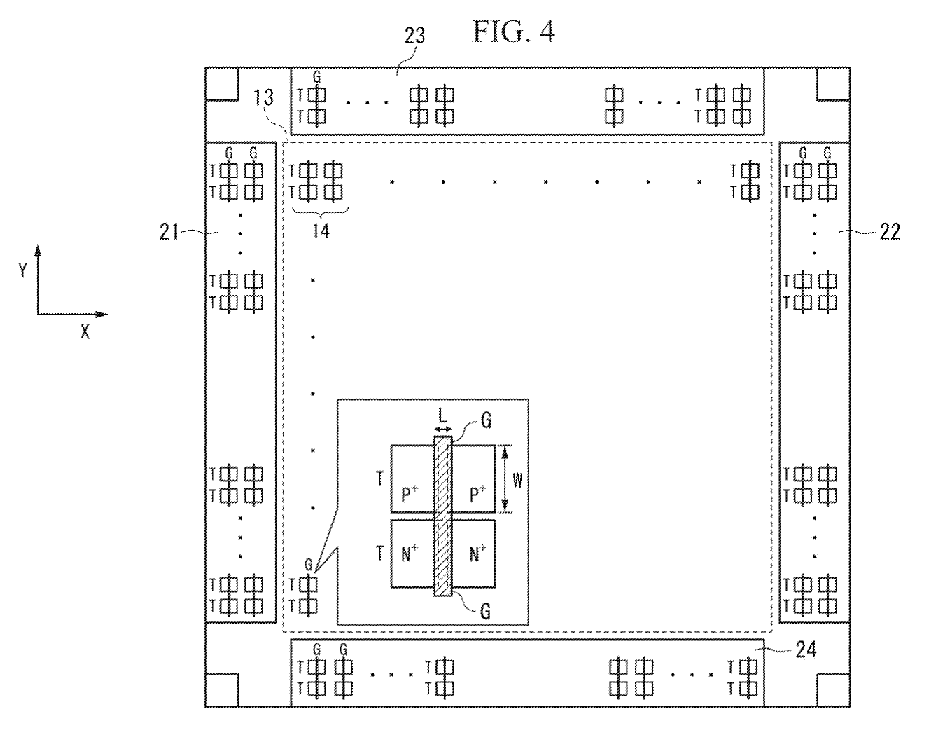

FIG. 4 shows a layout of an LSI chip according to the first embodiment. Specifically, the layout of an LSI chip shown in FIG. 4 includes interface cells (i.e. I/O buffers and I/O macros) 21, 22, 23, and 24 and standard cells (i.e. logic cells 14 in the logic circuit area 13).

As shown in FIG. 4, the upper/lower interface cells 23 and 24 agree with the left/right interface cells 21 and 22 as well as the logic circuit area 13 (serving as a core of an LSI chip) in terms of the directions of gates G of transistors T, i.e. length directions of gates G.

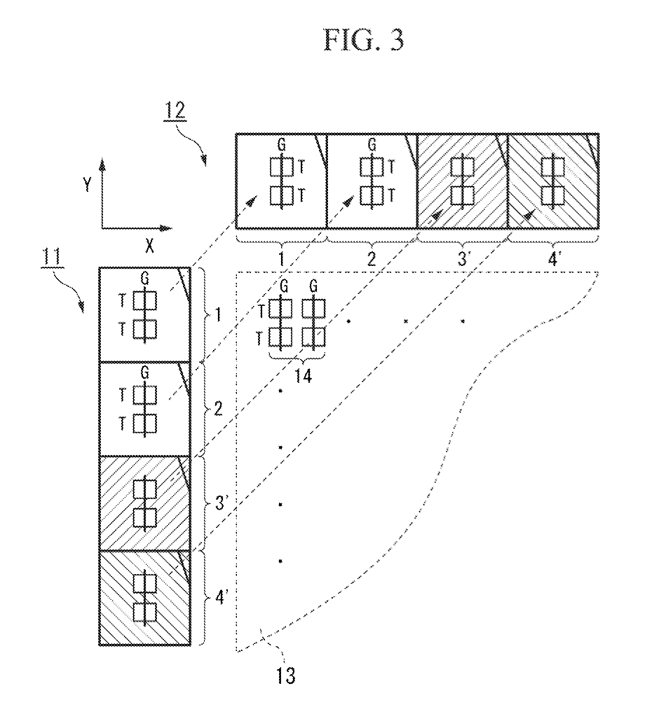

The first embodiment aims to align interface cells in the layouts shown in FIGS. 1 to 4, thus demonstrating the following effects.
(1) Engineers can neglect characteristic variations due to directional differences of transistors in an LSI chip, because the first embodiment unifies the direction of orientation among transistors included in interface cells in an LSI chip.
(2) It is possible to improve the performance of an LSI chip, because engineers can design the layout of an LSI chip without considering over-margins compensating for characteristic variations of transistors due to directional differences of transistors.
(3) It is possible to improve yields in manufacturing LSI chips, because the first embodiment unifies the direction of orientation among transistors in light of DFM (i.e. Design For Manufacturability).
(4) It is possible to reduce an overall size of an LSI chip, because the first embodiment does not need an additional circuit for correcting characteristic variations of transistors due to directional differences of transistors by unifying the direction of orientation among transistors. For example, a slave DLL (i.e. Delay Lock Loop) needs to be installed in an interface macro of DDR2 or DDR3 (where “DDR” stands for “Double Data Rate”), whereas it is difficult to precisely set a desired delay time when the direction of transistors of a slave DLL does not agree with the direction of transistors of a master DLL. Specifically, an LSI chip fabricating I/O macros along upper/left sides may need a master DLL having transistors whose direction agrees with the direction of transistors included in upper/left I/O macros. Since the first embodiment unifies the direction of orientation among transistors, the first embodiment may need a single master DLL with respect to all the upper/lower and left/right interface cells; this reduces the total number of master DLLs. The same concept can be adopted with respect to an impedance adjustment circuit for automatically setting output impedance.

### 2. Second Embodiment

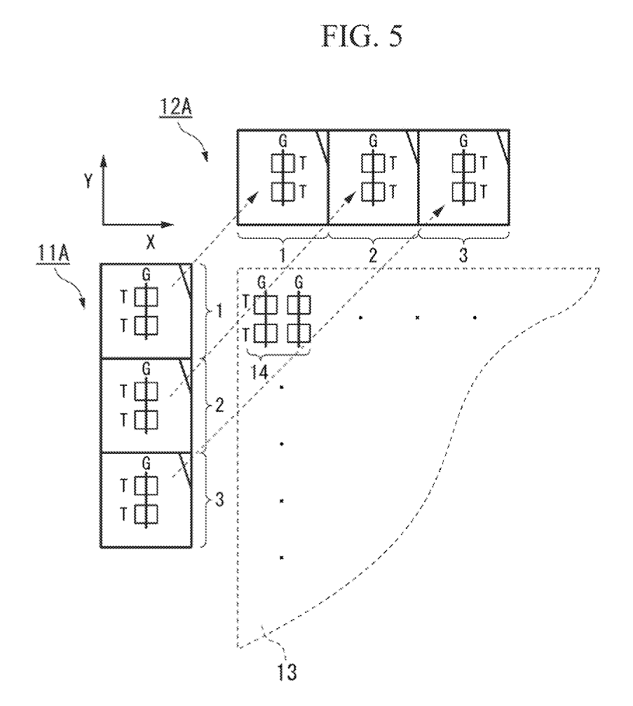

FIG. 5 shows a layout of interface cells (e.g. I/O buffers) in a semiconductor device according to a second embodiment of the present invention. The first embodiment is designed such that the I/O buffers 11 and 12 are each configured of four functional blocks 1 to 4; but the number of functional blocks included in each I/O buffer is not necessarily limited to four.

FIG. 5 shows I/O buffers 11A and 12A, each of which is configured of three functional blocks 1 to 3. An input/output circuit for inputting/outputting signals from/to logic cells 13 of the logic circuit area 13, a level conversion circuit for converging a core voltage (applied to the logic circuit area 13) into an I/O voltage, a CDM-ESD protective element, an output pre-buffer, and an input pre-buffer are disposed in the functional block 1 of the I/O buffer 11A/12A shown in FIG. 5. An output main buffer (juxtaposed to P-channel transistors), and an ESD protective element are disposed in the functional block 2. An output main buffer (juxtaposed to N-channel transistors) and an ESD protective element are disposed in the functional block 3.

In the left I/O buffer 11A (which is disposed along the left side of an LSI chip), the functional blocks 1 to 3 are vertically aligned in a Y-axis direction. In the upper I/O buffer 12A (which is disposed along the upper side of an LSI chip), the functional blocks 1 to 3 are realigned in parallel without being rotated at 90 degrees while maintaining the direction of transistors T and gates G and horizontally realigned in an X-axis direction. That is, the functional blocks 1 to 3, which are once assembled in the Y-axis direction as the I/O buffer 11A, are realigned in parallel along dotted allows without changing the direction of transistors T and gates G; subsequently, they are assembled in the X-axis direction so as to form the I/O buffer 12A.

The second embodiment is able to unify the direction of transistors T and gates G between the vertical layout of the left I/O buffer 11A and the horizontal layout of the upper I/O buffer 12A. Thus, engineers do not need to consider characteristic variations of transistors due to directional differences of transistors.

The second embodiment needs a small number of functional blocks in manufacturing an I/O buffer; that is, the I/O buffers 11A and 12A are each configured of three functional blocks 1, 2, and 3 as shown in FIG. 5. In other words, the second embodiment allows engineers to determine an optimum number of functional blocks in light of the maximum size of each functional block implementing a desired function. This reduces an overhead of a chip area as small as possible. In this connection, it is possible to fabricate on-chip capacitors in a vacant area within a chip area having a minimized overhead, thus improving noise resistance.

### 3. Third Embodiment

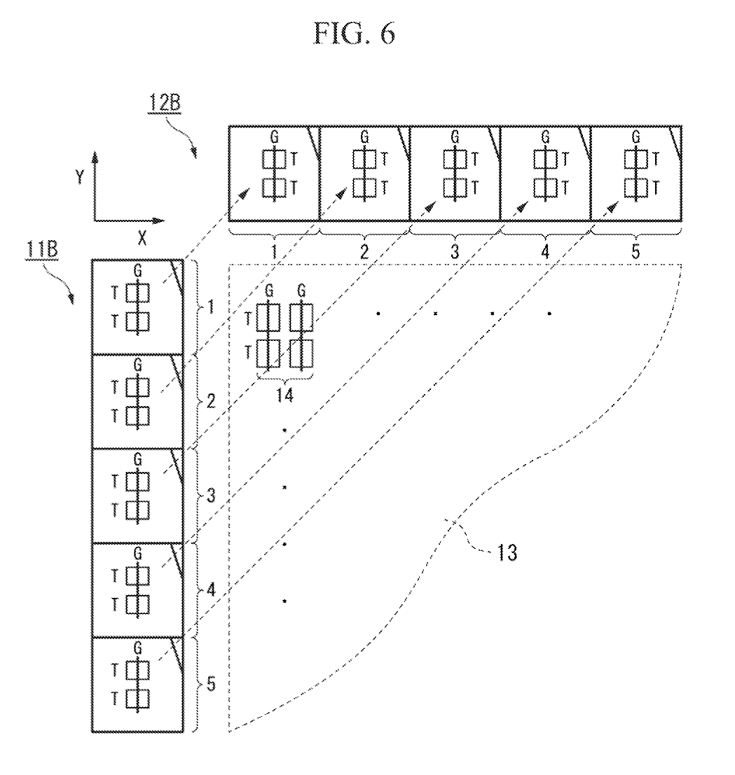

FIG. 6 shows a layout of interface cells (e.g. I/O buffers) in a semiconductor device according to a third embodiment of the present invention. In contrast to the second embodiment adopting the layout of FIG. 5 implementing three functional blocks 1 to 3, the third embodiment adopts the layout of FIG. 6 implementing five functional blocks 1 to 5.

FIG. 6 shows I/O buffers 11B and 12B in connection with the logic circuit area 13. An input/output circuit for inputting/outputting signals to/from the logic cell 14 of the logic circuit area 13 and a level conversion circuit for converting a core voltage (applied to the logic circuit area 13) into an I/O voltage are disposed in the functional block 1 of the I/O buffer 11B/12B. An output pre-buffer is disposed in the functional block 2. A CDM-ESD protective component and an input sense amplifier are disposed in the functional block 3. An output main buffer (juxtaposed to P-channel transistors) and an ESD protective component are disposed in the functional block 4. An output main buffer (juxtaposed to N-channel transistors) and an ESD protective component are disposed in the functional block 5.

In the left I/O buffer 11B (which is disposed along the left side of an LSI chip), the functional blocks 1 to 5 are vertically aligned in a Y-axis direction. In the upper I/O buffer 12B (which is disposed along the upper side of an LSI chip), the functional blocks 1 to 5 are realigned in parallel without being rotated at 90 degrees while maintaining the direction of transistors T and gates G and horizontally realigned in an X-axis direction. That is, the functional blocks 1 to 5, which are once vertically aligned in the Y-axis direction in the I/O buffer 11B, are realigned in parallel along dotted arrows without changing the direction of transistors T and gates G and horizontally realigned in the X-axis direction, thus assembling the I/O buffer 12B.

The third embodiment unifies the direction of transistors T and gates G with respect to both the vertical layout of the left I/O buffer 11B and the horizontal layout of the upper I/O buffer 12B; hence, engineers do not need to consider characteristic variations of transistors due to directional differences of transistors.

### 4. Fourth Embodiment

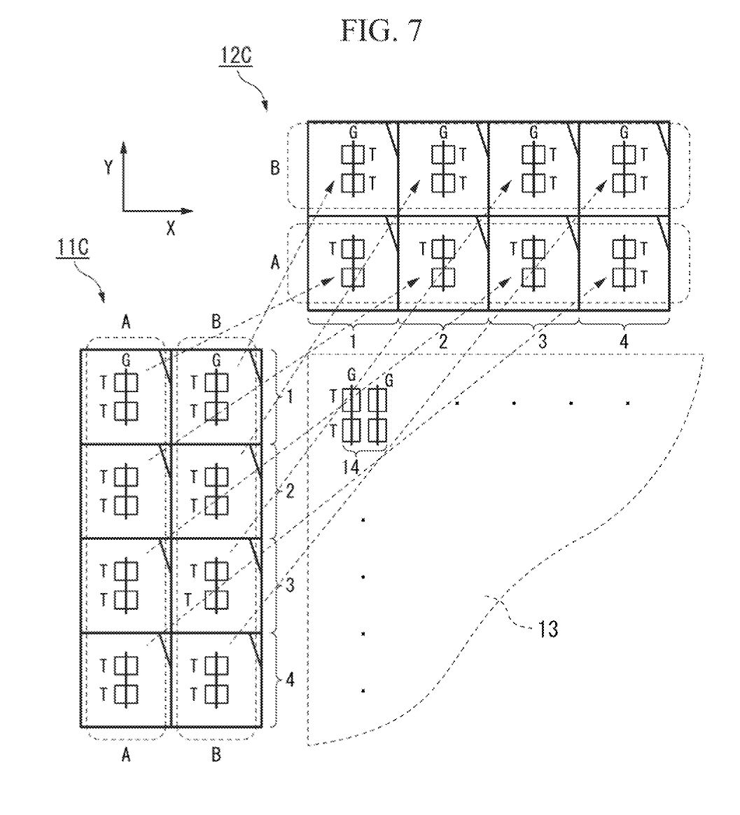

FIG. 7 shows a layout of interface cells (e.g. I/O buffers) in a semiconductor device according to a fourth embodiment of the present invention. The fourth embodiment adopts differential I/O buffers 11C and 12C as interface cells. Each of the differential I/O buffers 11C and 12C needs a double cell area juxtaposing two single-end I/O buffers A and B. FIG. 7 shows that each of the differential I/O buffers 11C and 12C is configured of eight functional blocks (i.e. 2×4=8) in total. The fourth embodiment can adopt differential I/O buffers by use of the layout of interface cells shown in FIG. 7.

The differential I/O buffer 11C/12C juxtaposes two single-end I/O buffers A and B, each of which includes four functional blocks 1 to 4. An input/output circuit for inputting/outputting signals to/from the logic cell 14 of the logic circuit area 13 and a level conversion circuit for converting a core voltage (applied to the logic circuit area 13) into an I/O voltage are disposed in the functional block 1. A CDM-ESD protective component, an output pre-buffer, and an input sense amplifier are disposed in the functional block 2. An output main buffer (juxtaposed to P-channel transistors) and an ESD protective component are disposed in the functional block 3. An output main buffer (juxtaposed to N-channel transistors) and an ESD protective component are disposed in the functional block 4.

In each of the single-end I/O buffers A and B fabricating the left-side differential I/O buffer 11C (which is disposed along the left side of an LSI chip), the functional blocks 1 to 4 are vertically aligned in a Y-axis direction. In each of the single-end I/O buffers A and B fabricating the upper-side differential I/O buffer 12C (which is disposed along the upper side of an LSI chip), the functional blocks 1 to 4 are realigned in parallel without being rotated at 90 degrees while maintaining the direction of transistors T and gates G and horizontally realigned in an X-axis direction. That is, the functional blocks 1 to 4, which are once vertically aligned in each of the single-end I/O buffers A and B of the left-side differential I/O buffer 11C, are realigned in parallel along dotted arrows without changing the direction of transistors T and gates G and horizontally realigned in an X-axis direction, thus assembling each of the single-end I/O buffers A and B of the upper-side differential I/O buffer 12C.

The fourth embodiment unifies the direction of transistors T and gates G with respect to both the vertical layout of the left-side differential I/O buffer 11C and the horizontal layout of the upper-side differential I/O buffer 12C; hence, engineers do not need to consider characteristic variations due to directional differences of transistors.

### 5. Fifth Embodiment

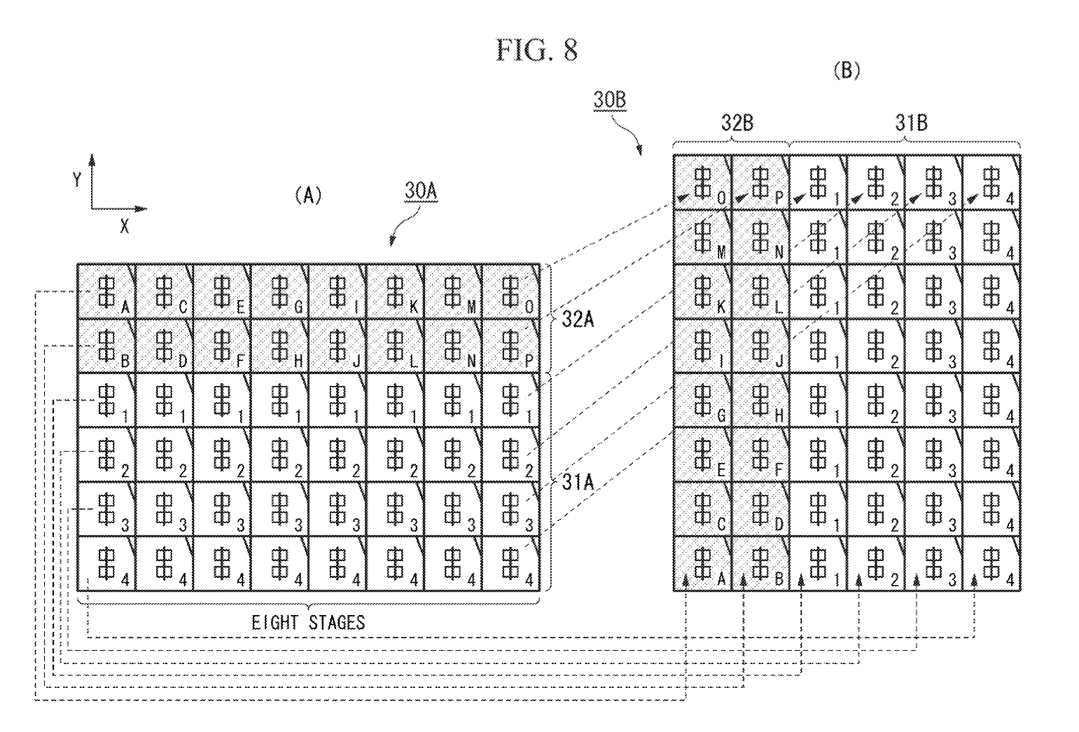

FIG. 8 shows layouts of interface cells (e.g. I/O macros) in a semiconductor device according to a fifth embodiment of the present invention. Specifically, FIG. 8(A) shows a layout of a left I/O macro 30A which is disposed along the left side of an LSI chip, and FIG. 8(b) shows a layout of an upper I/O macro 30B which is disposed along the upper side of an LSI chip.

The left I/O macro 30A of FIG. 8(A) is configured of an I/O buffer unit 31A and a logic unit 32A, each of which includes a plurality of I/O buffers. The upper I/O macro 30B shown in FIG. 8(B) is configured of an I/O unit 31B and a logic unit 32B, each of which includes a plurality of I/O buffers.

In the left I/O macro 30A of FIG. 8(A), the I/O unit 31A includes eight sets of four functional blocks, wherein the four functional blocks 1 to 4 are vertically aligned in a Y-axis direction, and the eight sets of functional blocks are juxtaposed in eight rows in an X-axis direction; that is, the I/O unit 31A is configured of eight single-end I/O buffers. The logic unit 32A includes eight sets of two functional blocks, wherein the two functional blocks (i.e. A and B; C and D; E and F; G and H; I and J; K and L; M and N; 0 and P) are vertically aligned in a Y-axis direction, and the eight sets of functional blocks are juxtaposed in eight rows in an X-axis direction.

When the left I/O macro 30A of FIG. 8(A) is rearranged as the upper I/O macro 30B of FIG. 8(B), six functional blocks 1, 2, 3, 4, A and B, which are vertically aligned in a Y-axis direction, are realigned in parallel without being rotated at 90 degrees (without changing the direction of transistors T and gates G) and horizontally realigned in an X-axis direction. That is, eight sets of six functional blocks (namely, functional blocks 1 to 4 and A to P) are each rearranged between the left I/O macro 30A and the upper I/O macro 30B in such a way that six functional blocks 1, 2, 3, 4, A and B, which are once vertically aligned in a Y-axis direction, are realigned in parallel along dotted arrows without changing the direction of transistors T and gates G and horizontally realigned in an X-axis direction.

The fifth embodiment unifies the direction of transistors T and gates G with respect to both the vertical layout of the left I/O macro 30A and the horizontal layout of the upper I/O macro 30B; hence, engineers do not need to consider characteristic variations due to directional differences of transistors.

The foregoing embodiments of the present invention illustrates that each interface cell (e.g. an I/O buffer) has a layout of functional blocks having rectangular shapes (e.g. square shapes), and functional blocks are not rotated but simply realigned to form the vertical layout with respect to the upper/lower sides of an LSI chip and to form the horizontal layout with respect to the left/right sides of an LSI chip. The foregoing embodiments are not necessarily limited to a single I/O buffer but applicable to an I/O macro (e.g. a Serializer/Deserializer (SerDes) and a DDR-I/F macro) including a plurality of I/O buffers and control logics.

Interface cells are not necessarily limited to I/O buffers and I/O macros but applicable to input circuits (e.g. address buffers) and output circuits (e.g. data-out buffers).

Interface cells are not necessarily disposed along four sides of an LSI chip. That is, the foregoing embodiments are applicable to interface cells (e.g. I/O buffers) disposed in the periphery of a center pad in a center-pad configuration (in which input/output pads are collectively disposed at the center of an LSI chip).

The present invention is applicable to semiconductor chips having multiple types of macro cells. For example, the present invention can be applied to interface cells interposed between macro cells serving as DRAM and SDRAM (i.e. Synchronous DRAM) and other macro cells on semiconductor chips.

A supplementary explanation will be described with respect to the correspondence between the terms used in the foregoing embodiments and the claim languages. As to FIG. 1, the I/O buffers 11 and 12 are regarded as “interface cells”; the functional blocks 1 to 4 are regarded as “functional blocks”; and the logic cells 14 of the logic circuit area 13 are regarded as “logic cells”. In addition, the functional block 1 is regarded as a “first functional block”; the functional block 2 is regarded as a “second functional block”; the functional block 3 is regarded as a “third functional block”; and the functional block 4 is regarded as a “fourth functional block”. As to FIG. 7, the I/O buffers 11C and 12C are regarded as “interface cells”. As to FIG. 8, the I/O macros 30A and 30B are regarded as “interface cells”.

The first embodiment of FIG. 1 includes the I/O buffers 11 and 12, which are connected to the logic cells 14 of the logic circuit area 13 (serving as a core of an LSI chip), which supply external signals (i.e. signals from an external device) to the logic cells 14, which output signals from the logic cells 14 to the external device, or which input/output signals to/from the logic cells 14. Each of the I/O buffers 11 and 12 further includes the functional blocks 1 to 4 each having a rectangular shape, wherein the functional blocks 1 to 4 agree with the logic cells 14 in terms of the length direction of gates G of transistors T.

When arranging the I/O buffers 11 and 12 in the periphery of an LSI chip, engineers do not need to consider characteristic variations due to directional differences of transistors.

Each of the I/O buffers 11 and 12 includes the functional block 1 (which further includes an input/output circuit for inputting/outputting signals to/from the logic cells 14 of the logic circuit area 13 and a level conversion circuit for converting a core voltage into an I/O voltage), the functional block 2 (which further includes an output pre-buffer and an input sense amplifier), the functional block 3 (which further includes an output main buffer juxtaposed to P-channel transistors), and the functional block 4 (which further includes an output main buffer juxtaposed to N-channel transistors).

Thus, engineers do not need to consider characteristic variations due to directional differences of transistors when arranging the “bidirectional” I/O buffers 11 and 12 in the periphery of an LSI chip.

In FIG. 2, in which the length direction of gates G is regarded as a vertical direction while a direction perpendicular to the length direction of gates G is regarded as a horizontal direction, a power-wiring structure having a mesh structure includes at least two power-wiring layers formed above I/O buffers and functional cells, wherein the first power-wiring layer includes the ground lines G1 to Gn and the power lines V1 to Vn both of which are laid in the vertical direction, while the second power-wiring layer includes the ground lines G1′ to Gn′ and the power lines V1′ to Vn′ both of which are laid in the horizontal direction.

The above structure facilitates power-wirings with ease, because engineers simply arrange the functional blocks 1 to 4 at adjacent positions so as to properly establish power connections with the functional blocks 1 to 4 with respect to either the vertical layout of the I/O buffer 11 or the horizontal layout of the I/O buffer 12.

In the fourth embodiment of FIG. 4, each of the differential I/O buffers 11C and 12C juxtaposes the two I/O buffers A and B each of which includes the four functional blocks 1 to 4. Herein, the eight functional blocks (i.e. 2×4=8), which is included in each of the differential I/O buffers 11C and 12C, agree with the logic cells 14 of the logic circuit area 13 in terms of the length direction of gates G of transistors T. That is, engineers do not need to consider characteristic variations due to directional differences of transistors with respect to differential I/O buffers.

In the fifth embodiment of FIG. 8, the I/O macros 30A, 30B are respectively constituted of the I/O units 31A, 31B and the logic units 32A, 32b, which are connected together. Each of the I/O units 31A, 31B is configured of thirty-two functional blocks (i.e. 8×4=32) including eight sets of four functional blocks which are juxtaposed together, while each of the logic units 32A, 32B is configured of sixteen functional blocks including eight sets of two functional blocks which are juxtaposed together. Herein, the same length direction of gates of transistors is uniformly set to thirty-two functional blocks of each I/O unit 31, sixteen functional blocks of each logic unit 32, and logic cells of the logic circuit area. That is, engineers do not need to consider characteristic variations due to directional differences of transistors with respect to I/O macros.

Lastly, the present invention is not necessarily limited to the illustrative embodiments of semiconductor devices, which can be further modified within the scope of the invention as defined in the appended claims.

What is claimed is:

1. A semiconductor device comprising:
a plurality of logic cells;
a plurality of interface cells which are disposed in connection with the plurality of logic cells,
wherein each interface cell is configured of a plurality of functional blocks each including a plurality of transistors having gates whose length direction agrees with a length direction of gates of transistors included in each logic cell.

2. The semiconductor device according to claim 1, wherein each interface cell is configured of an I/O buffer.

3. The semiconductor device according to claim 2, wherein the I/O buffer includes a first functional block which further includes an input/output circuit for inputting/outputting signals with each logic cell and a level conversion circuit for converting a core voltage into an I/O voltage, a second functional block which further includes an output pre-buffer and an input sense amplifier, a third functional block which further includes an output main buffer juxtaposed to a P-channel transistor, and a fourth functional block which further includes an output main buffer juxtaposed to an N-channel transistor.

4. The semiconductor device according to claim 1 further comprising a power-wiring structure having a mesh structure constituted of a first power-wiring layer and a second power-wiring layer both of which are formed above the interface cells and the logic cells, wherein the first power-wiring layer conducts power wirings in a vertical direction corresponding to the length direction of gates of transistors, while the second power-wiring layer conducts power wirings in a horizontal direction perpendicular to the length direction of gates of transistors.

5. The semiconductor device according to claim 1, wherein each interface cell is configured of m×n functional blocks (where m, n are integers not less than “2”) in which m functional blocks are serially aligned together whilst n sets of m functional blocks are juxtaposed together, and wherein the length direction of gates of transistors included in the m×n functional blocks agrees with the length direction of gates of transistors included in the logic cells.

6. The semiconductor device according to claim 1, wherein each interface cell serves as an I/O macro including an I/O unit and a logic unit which are connected together,
wherein the I/O unit is configured of m×n functional blocks (where m, n are integers not less than “2”) in which m functional blocks are serially aligned together whilst n sets of m functional blocks are juxtaposed together,
wherein the logic unit is configured of m′×n functional blocks (where m′ is an integer not less than “2”) in which m′ functional blocks are serially aligned together whilst n sets of m′ functional blocks are juxtaposed together, and
wherein the same length direction of gates of transistors is uniformly set to the logic cells, the m×n functional blocks included in the I/O unit, and the m′×n functional blocks included in the logic unit.

7. An alignment method of interface cells which are connected to logic cells in a semiconductor device, comprising:
align a plurality of functional blocks so as to form each interface cell; and
aligning a plurality of transistors in each function block with a predetermined length direction of gates in conformity with the length direction of gates of transistors included in each logic cell.
